(19) United States
(12) Patent Application Publication
(10) Pub. No.: US 2010/0010761 A1
(43) Pub. Date: Jan. 14, 2010

(54) METHOD AND DEVICE FOR MONITORING A SYSTEM

(75) Inventors: Sven Nordebo, Lammhult (SE); Thomas Biro, Vetlanda (SE); Jonas Lundbäck, Vaxjo (SE)

Correspondence Address: BIRCH STEWART KOLASCH & BIRCH, PO BOX 747, FALLS CHURCH, VA, 22040-0747, US

(73) Assignee: WAVETECH SWEDEN AB, Vaxjo (SE)

(21) Appl. No.: 12/443,652

(22) PCT Filed: Sep. 26, 2007
(86) PCT No.: PCT/SE2007/000841

§ 371 Date: Apr. 27, 2009

(30) Foreign Application Priority Data
Sep. 29, 2006 (SE) 0602043-2

(51) Int. Cl. G06F 19/00; G01R 23/16; G01R 35/00

(52) U.S. Cl. 702/70; 702/106

(57) ABSTRACT

The present invention relates to a method and a device for monitoring a system such as a cable. Pulses propagating in different directions are distinguished by measuring and sampling current and voltage at a location of the system, frequency transforming the obtained signals, and by extracting signals corresponding to pulses propagating in different directions as linear combinations of the frequency-transformed signals. Such a method is applicable, e.g. when monitoring occurrences of partial discharge on a 10 kV cable.

### TECHNICAL FIELD

The present invention relates to a method and a device for monitoring a system, such as a medium-voltage cable.

### BACKGROUND

Such a device is disclosed e.g. in “On-line signal analysis of partial discharges in medium-voltage power cables” by J. Veen, PhD Thesis Eindhoven University of Technology, The Netherlands. The device disclosed in that document is used to indicate occurrences of partial discharges (PD) on medium-voltage cables. PDs usually generate broadband pulses which represent error-indicating data.

One problem associated with such devices is how to apply a functionality that provides discrimination between error-indicating data that originates from the system under test, e.g. a cable, and similar data originating from other sources.

Typically, conventional directional couplers, which per se are known from microwave technology applications, may be used to this end. The directional coupler may then provide the ability to determine whether a pulse, constituting error-indicating data, propagates in one direction or the other. However, e.g. in a high-voltage context, application of such directional couplers may prove difficult and may result in complex and expensive arrangements.

### SUMMARY OF THE INVENTION

An object of the present invention is to provide a method and a device for monitoring a system which wholly or in part obviates the above mentioned problem.

This object is achieved by means of a method for monitoring a system as defined in claim 1 and a corresponding device as defined in claim 9.

More specifically, the method involves measuring and sampling at least two linearly independent combinations of voltage and current at a location of the system, such that a first and a second time-domain signal is provided, applying a frequency transform on the first and second time-domain signals, such that first and second frequency-domain signals are provided, and extracting, in the frequency domain, a signal, corresponding to a pulse propagating in one direction, as a linear combination of the first and second frequency-domain signals.

This allows the discrimination between pulses propagating in first and second direction without the use of conventional hardware directional couplers, which is particularly useful in on-line monitoring of a high-voltage application.

The frequency transform may be applied using a Fast Fourier Transform, FFT.

Further, a signal, corresponding to a pulse propagating in a direction opposite to said one direction may be extracted, as a linear combination of the first and second frequency-domain signals.

A signal, extracted in the frequency domain, may further be inversely transformed to the time domain.

A calibration procedure of a monitoring system, to be used for the determining of the propagating direction of a pulse, may be carried out by attaching a calibration arrangement to a device under test with an impedance mismatched interface, and by propagating a pulse towards the interface, such that a transmitted pulse may be sensed by the monitoring system and a reflected pulse may be sensed by the calibration arrangement.

The initially mentioned method for monitoring may be carried out as a method for monitoring a high-voltage system, such as for detecting partial discharge conditions in a cable, or for detecting transient conditions.

The object is further achieved by means of a device corresponding to the above mentioned method. Generally, the device then comprises means for carrying out the steps of the method. The device may be varied in accordance with the method.

### BRIEF DESCRIPTION OF THE DRAWINGS

FIG. 1 illustrates a context where a method according to the invention may be applied.

FIG. 2 illustrates as a flow-chart, a method for monitoring a high-voltage system.

FIG. 3 illustrates functional blocks in a monitoring arrangement.

FIG. 4 illustrates a calibration set-up for determining parameters for use in monitoring a medium-voltage cable.

FIG. 5 illustrates a timing diagram for a calibration procedure.

FIGS. 6-9 illustrate signals generated by different blocks in a monitoring system.

### DETAILED DESCRIPTION

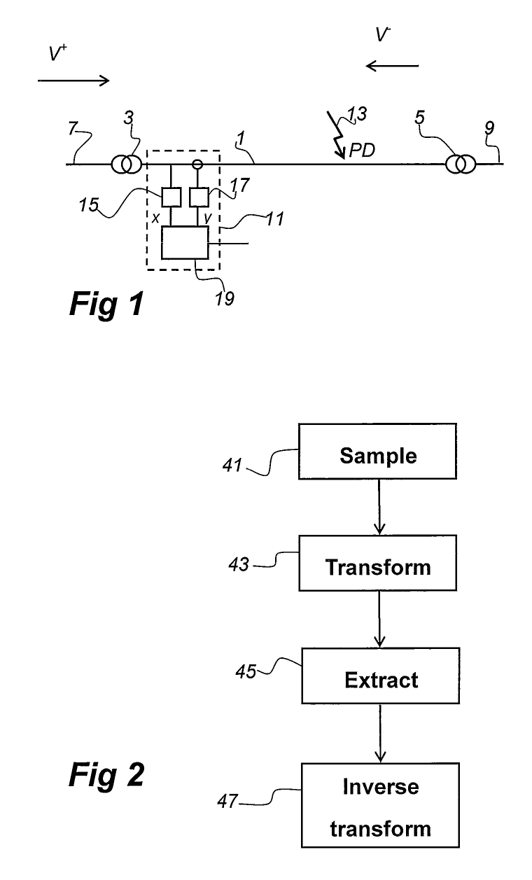

FIG. 1 illustrates a context where the method is applied. A transmission line power cable 1 is used in a transmission grid sub-system to connect, via first and second transformers 3, 5 a high-voltage (e.g. 100 kV) transmission grid 7 with a low-voltage system 9 (e.g. 400 V). The transmission line power cable 1 may typically be called a medium-voltage cable, and typically operates at an alternating voltage of e.g. 10 kV. A monitoring system 11 is used to monitor the performance of the cable 1 during use, particularly to detect partial discharge (PD) occurrences.

PD may occur due to imperfect insulation in the cable, and PD occurrences may be used to predict for instance a cable malfunction. Determining the occurrence of PD conditions in a cable can therefore be used as a part of a maintenance planning tool.

Usually, a PD condition results in a series of broadband pulses being emitted from the PD location 13 on the cable 1. The pulses are typically emitted during the part of each alternating voltage half-period when the instantaneous voltage is close to its maximum. The pulses reach the monitoring system 11 from the right as illustrated in FIG. 1.

It is assumed that the low-voltage system 9 does not to any greater extent exhibit PD occurrences, thanks to the lower voltage. Other similar pulses may be emitted, e.g. due to the use of thyristors and the like, but these pulses may be discarded either by filtering or by different statistical analyses. PDs may then e.g. be distinguished since they are often load independent, etc.

In the high-voltage transmission grid 7 however, PDs may occur as well as in other subsystems, connected to the high-voltage transmission grid 7. The PD pulses produced in the transmission grid or in other sub-systems may propagate to the monitoring system 11 and may reach this sub-system from the left as illustrated in FIG. 1.

The pulses from the left and from the right are superpositioned at the monitoring system. In order to be able to determine whether the pulses originate from the cable 1 or not, the propagating direction of the pulses will have to be decided. As mentioned, this may be achieved using conventional directional couplers. Below, a different method is described, which is better suited for performing monitoring e.g. in high-voltage environments. By a high-voltage system is herein meant a system operating at a line voltage higher than 380 volts. Thus, so called medium-voltage cables are regarded as high-voltage systems in this context.

The illustrated monitoring system 11 comprises a capacitive sensor 15 and an inductive sensor 17. Both sensors are placed at the end of the cable 1 that is closest to the transmission grid 7. The capacitive sensor 15 outputs the signal x(t), and the inductive sensor 17 outputs the signal y(t). In the example described below, x(t) is a voltage proportional to the cable voltage, and y(t) is a voltage proportional to the cable current. However, it is sufficient that x(t) and y(t) represent two linearly independent combinations of the cable voltage and current.

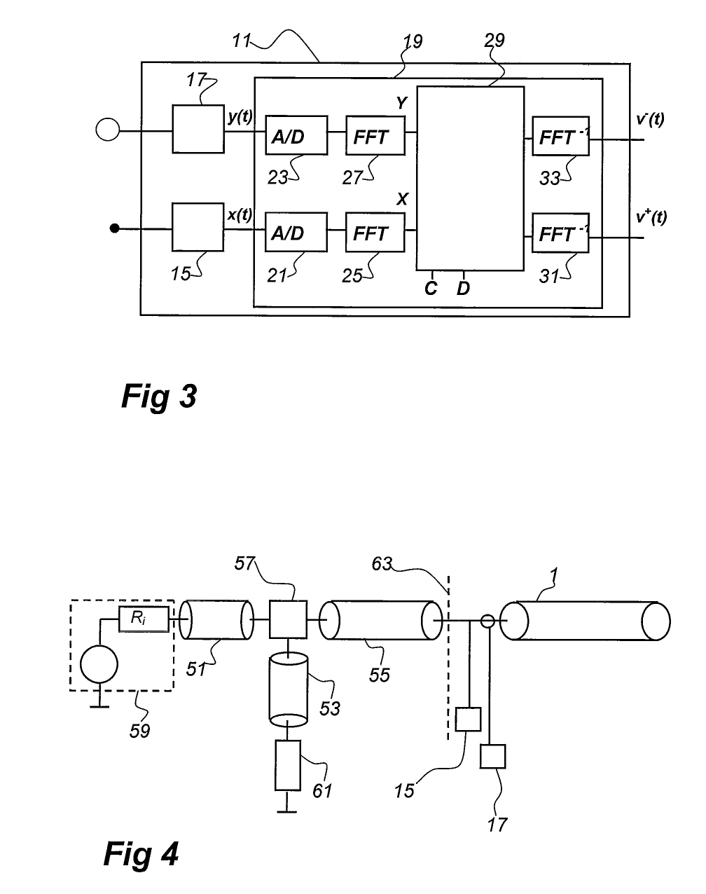

These signals are processed by a signal processing block 19 as will now be described with reference to FIG. 3.

As is well known, the voltage and current at every position of the cable may be described in the frequency domain by:

$$\{ \begin{matrix}V ( l ) = {V}^{+} {e}^{- γ l} + {V}^{-} {e}^{γ l} \\ I ( l ) = \frac{{V}^{+}}{Z} {e}^{- γ l} - \frac{{V}^{-}}{Z} {e}^{γ l}\end{matrix} , \qquad ( Eq 1 )$$

where V⁺ and V⁻ denote the complex amplitudes of the pulses traveling to the right and to the left, respectively, in FIG. 1, γ the complex propagation constant, l the length dimension, and Z the characteristic impedance of the cable.

In the frequency domain, these amplitudes may be expressed as:

$$( \begin{matrix}{V}^{+} \\ {V}^{-}\end{matrix} ) = ( \begin{matrix}\frac{1}{2} & \frac{1}{2} Z \\ \frac{1}{2} & - \frac{1}{2} Z\end{matrix} ) ( \begin{matrix}V ( 0 ) \\ I ( 0 )\end{matrix} ) . \qquad ( Eq 2 )$$

It may further be assumed that the capacitive and inductive sensors 15, 17 output signals x(t), y(t), which in the frequency domain may be expressed as:

$$\{ \begin{matrix}X = AV ( 0 ) \\ Y = BI ( 0 ) ,\end{matrix} \qquad ( Eq 3 )$$

where A and B are the corresponding frequency functions of the sensors.

There is thus a linear one-to-one relationship in the frequency domain between the signals X, Y and the wave amplitudes V⁺, V⁻, which may be expressed as:

$$( \begin{matrix}{V}^{+} \\ {V}^{-}\end{matrix} ) = ( \begin{matrix}C & D \\ C & - D\end{matrix} ) ( \begin{matrix}X \\ Y\end{matrix} ) , C = \frac{1}{2 A} , D = \frac{Z}{2 B} \qquad ( Eq 4 )$$

It is therefore possible to extract the right (V⁺) and left (V⁻) propagating pulses (cf. FIG. 1) in the frequency domain with proper knowledge of the frequency domain parameters C and D. This may be carried out by means of a signal processing block 19 as will now be described in greater detail with reference to FIGS. 2 and 3. FIG. 2 describes four steps carried-out in the method, and FIG. 3 illustrates functional blocks used to carry out these steps. To a great extent, the method is carried out by means of signal processing. Except for the sensors, the functional blocks may therefore be realized as software routines executed on a digital signal processor (DSP) or a central processing unit (CPU). It is however possible to realize some or all of the blocks as hardware, e.g. using an application specific integrated circuit (ASIC). Means for carrying out a function may thus be realized as software, hardware, firmware, or combinations thereof.

With reference to FIGS. 2 and 3, the voltage and current signals x(t), y(t) from the capacitive and inductive sensors 15, 17 are sampled and converted to a digital format 41 in the time domain, using analog-to digital converters 21, 23, respectively. For partial discharges a bandwidth of e.g. 50 MHz may be considered. The sampling is carried out at a sampling rate exceeding the Nyquist rate, i.e. higher than twice the desired bandwidth. The sampled signals may be divided into blocks (e.g. 1024 samples) and may be zero-padded, as is well known per se, in order to prepare the data for frequency domain transformation.

An example of corresponding signals x(t) and y(t) is illustrated in FIGS. 6 and 7, respectively.

The signal data is then transformed 43 to the frequency domain using e.g. the fast Fourier transform, FFT, as realized in a first and a second FFT block 25, 27, respectively. The outputs of the FFT blocks 25, 27 will thus be digital versions of the signals x(t) and y(t), respectively, which are transformed into the frequency domain as X and Y.

It is now possible to extract 45, still in the frequency domain, the right- and left-propagating wave amplitudes V⁺ and V⁻ as linear combinations of X and Y as illustrated in (Eq 4) above.

This is done in a calculation block 29. Parameters C and D, are provided to the calculation block 29, as determined e.g. by means of a calibration procedure which will be described later.

Once V⁺ and V⁻ have been determined in the frequency domain, the corresponding time domain signals may be determined by applying 47 an inverse transform, such as an inverse FFT on each frequency domain signal. This inverse transform may be carried out by means of inverse transform blocks 31 and 33, respectively, for signals V⁺ and V⁻, thereby obtaining time domain signals v⁺(t) and v⁻(t). However, it is also possible to base a monitoring function on a signal as determined in the frequency domain. The use of the inverse transform may therefore be optional.

Left and right propagating signals in the time domain as extracted are illustrated in FIGS. 8 and 9, respectively. It may in particular be noted that the pulses, indicated by arrows in FIGS. 6 and 7, have been determined to propagate to the right and thus are present only in v⁺(t) which is illustrated in FIG. 8. The measurements illustrated in FIGS. 6-9 have been performed on a coaxial cable, using a capacitive and an inductive sensor, a digital sampling oscilloscope, and a PC to perform the signal processing algorithm.

As outputs from the calculation block 29 alternative signals are possible, as mentioned. Signals corresponding to the left or right propagating pulses, either in the time domain or in the frequency domain are outputted and may be analyzed in subsequent processes. These processes may result in an alarm signal being sent to an operator if a signal originating in the cable 1 indicates that PDs occur.

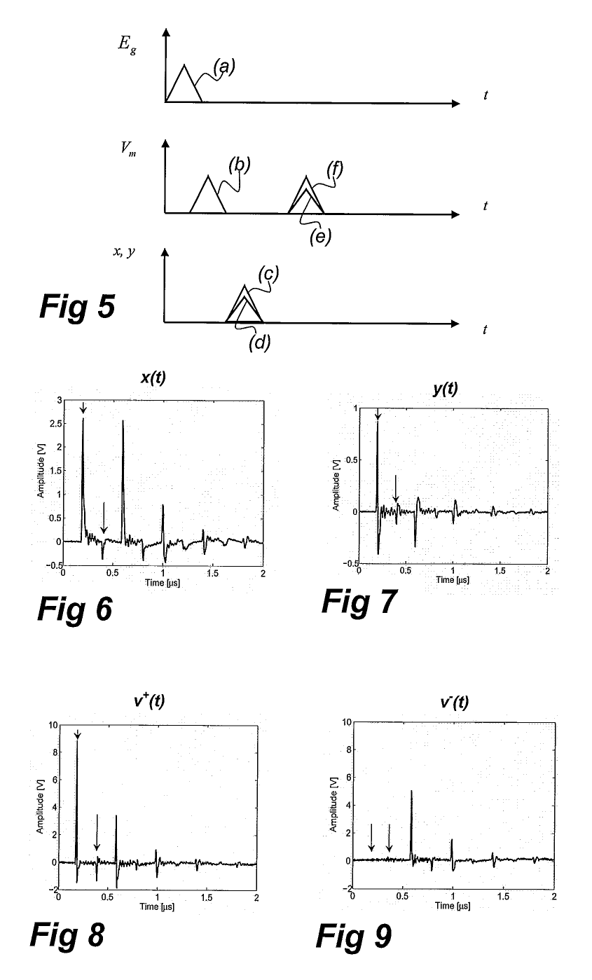

There will now be described a method for calibrating the above-described system, i.e. a method for obtaining parameters C, and D as mentioned above. FIG. 4 illustrates schematically a calibration set-up for determining parameters for use in monitoring a medium-voltage cable 1. FIG. 5 illustrates a timing diagram for signals occurring during the calibration procedure.

A system, comprising three 50 (coaxial cables, 51, 53, 55 which are inter-connected by a 50Ω splitter 57, is used. A pulse generator 59 having an internal resistance Rᵢ is connected to the first 50Ω cable 51 at the end opposite to the 50Ω splitter 57. The second 50Ω cable 53 is connected between the 50Ω splitter 57 and a sensor resistor 61, over which a voltage Vₘ is measured during calibration. The third 50Ω cable 55 is connected between the 50Ω splitter 57 and the medium voltage cable 1, which is now off line. Every junction in the set-up is matched (or just about), except the junction/interface 63 between the third 50Ω cable 55 and the medium voltage cable 1. At the latter junction, the monitoring system 11 as described above is connected, which in FIG. 4 is illustrated by the capacitive and inductive sensors 15 and 17, which generate signals x(t) and y(t).

The calibration procedure is carried out in two steps, which may be carried out in any order. In a first step, pulse generator 59 generates a pulse (a), which is illustrated in the top section of FIG. 5. This pulse propagates through the first 50Ω cable 51 and is then split in two equal parts, which propagate through the second and third 50Ω cables 53 and 55, respectively. At the end of the second 50Ω cable 53 a signal (b) is measured at the sensor resistor 61, as illustrated in the mid section of FIG. 5. At the monitoring system 11 x(t) and y(t) are measured ((c) and (d), respectively in FIG. 5). At this location the pulse is further reflected to some extent due to the above-mentioned mismatch. The reflected pulse propagates through the third 50Ω cable and is again split in the 50Ω splitter 57. Some of the pulse energy will thus reach the pulse generator 59 and will be effectively eliminated by the latter's internal resistance Rᵢ. The rest of the reflected pulse energy will be consumed by the sensor resistance 61 where it will be measured (e).

It is assumed above that the length of the medium-voltage cable 1 is sufficiently long, so that any reflection generated at the other end of the cable arrives too late at the calibration set-up to disturb this measurement.

In a second step, the cable 1 is disconnected, and replaced by a short-circuit. The above procedure is then repeated by generating a pulse at the pulse generator. In this case x(t) and y(t) are of course not measured, but a new reflected pulse (f) is measured at the sensor resistor 61 as is illustrated in the same timing diagram as the first measurement. Note that the second step does neither depend on the monitoring system 11, nor the cable 1 under test. Therefore this step need only be carried out once for the calibration set-up.

When this set of data has been collected, the parameters C and D can be determined as follows. First, the signals are transformed into the frequency domain, and the reflection coefficient, where the medium-voltage cable 1 is connected to the third 50Ω cable 55, is determined as:

$${Γ}^{+} = - \frac{{V}_{m}^{( 1 )}}{{V}_{m}^{( s )}} ,$$

where Vₘ⁽¹⁾ is signal (e) in the frequency domain, and Vₘ^{(s)} is the corresponding signal (f). The signal V₂⁺⁽¹⁾ reaching the monitoring system 11 during the first step may then be determined in the frequency domain as:

V₂⁺⁽¹⁾=Vₘ⁽⁰⁾e^{-γ}^{₀}^{(l-l}^{₀₎}(1+Γ⁺),

where Vₘ⁽⁰⁾ corresponds to the signal (b), l is the length of the third 50 Ω cable 55, l₀ is the length of the second 50 Ω cable 53, and γ₀ is the propagation constant of the second and third 50Ω cables 53, 55.

With reference to Equation 4, parameters C and D may now be determined as:

$$C = \frac{{V}_{2}^{+ ( 1 )}}{2 X} , D = \frac{{V}_{2}^{+ ( 1 )}}{2 Y} ,$$

where X and Y correspond, in the frequency domain, to pulses (c) and (d) in FIG. 5.

These parameters C and D may then be used in an on-line measurement as described earlier.

Essentially, the calibration scheme relies on attaching a calibration arrangement, having a pulse generator, to the device under test via an impedance mismatched interface 63. A pulse is generated by the pulse generator and is sent towards the interface. The part of the pulse that is transmitted by the interface is sensed by capacitive and inductive sensors in the monitoring arrangement and a reflected pulse is sensed in the calibration arrangement. With proper knowledge of the reflection coefficient in the interface, parameters may be determined that may be used in the monitoring method.

Needless to say, other calibration schemes are possible and may be realized by the skilled person.

In summary, the invention relates to a method and a device for monitoring a system such as a cable. Pulses propagating in different directions are distinguished by measuring and sampling current and voltage at a location of the system, frequency transforming the obtained signals, and by extracting signals corresponding to pulses propagating in different directions as linear combinations of the frequency-transformed signals. Such a method is applicable, e.g. when monitoring occurrences of partial discharge on a 10 kV cable.

The invention is not restricted by the described embodiments. It may be varied and altered in different ways within the scope of the appended claims.

For instance, other means for frequency domain transformation than FFT are possible as is well known to the skilled person. Additionally, even if the above method has been illustrated in an application where partial discharges in medium-voltage cables are detected, other implementations are possible, such as other partial discharge monitoring applications, e.g. in relation to transformers or cable joints.

The inventive method may also be useful for transient protection systems.

1. Method for monitoring a system by determining the propagating direction of a pulse comprising the steps of:
measuring and sampling (41) at least two linearly independent combinations of voltage and current at a location of the system, such that a first (x(t)) and a second (y(t)) time-domain signal is provided,
applying a frequency transform (43) on the first and second time-domain signals, such that first (X) and second (Y) frequency-domain signals are provided, and
extracting (45), in the frequency domain, a signal (V⁻), corresponding to a pulse propagating in one direction, as a linear combination of the first and second frequency-domain signals.

2. A method according to claim 1, wherein the frequency transform is applied using a Fast Fourier Transform, FFT.

3. A method according to claim 1, wherein further a signal (V⁺), corresponding to a pulse propagating in a direction opposite to said one direction is extracted, as a linear combination of the first and second frequency-domain signals.

4. A method according to claim 1, wherein a signal (V⁻), extracted in the frequency domain, is inversely transformed (47) to the time domain (v⁻(t)).

5. A method according to claim 1, wherein a calibration procedure of a monitoring system to be used for said detection of the propagating direction of a pulse is carried out by attaching a calibration arrangement to a system under test with an impedance mismatched interface, and propagating a pulse towards the interface, such that a transmitted pulse may be sensed by the monitoring system and a reflected pulse may be sensed by the calibration arrangement.

6. A method as claimed in claim 1, wherein the method for monitoring is carried out as a method for monitoring a high-voltage system.

7. Method as claimed in claim 6, wherein the method for monitoring is carried out in a method for detecting partial discharge conditions in a cable.

8. Method as claimed in claim 6, wherein the method for monitoring is carried out in a method for detecting transient conditions.

9. Device for monitoring a system by means for determining the propagating direction of a pulse comprising:
means for measuring (15, 17) and sampling (21, 23) at least two linearly independent combinations of voltage and current at a location of the system, such that a first (x(t)) and a second (y(t)) time-domain signal is provided,
means for frequency transforming (25, 27) the first and second time-domain signals, such that first (X) and second (Y) frequency-domain signals are provided, and
means for extracting (29), in the frequency domain, a signal, corresponding to a pulse propagating in one direction, as a linear combination of the first and second frequency-domain signals.

10. Device according to claim 9, wherein the frequency transform is applied using a Fast Fourier Transform, FFT.

11. Device according to claim 9, wherein the device further comprises means for extracting a signal, corresponding to a pulse propagating in a direction opposite to said one direction, as a linear combination of the first and second frequency-domain signals.

12. Device according to claim 9, wherein the device comprises means (31, 33) for inversely transforming a signal, extracted in the frequency domain, to the time domain.

13. Device according to claim 9, wherein the device further comprises a calibration arrangement, which is adapted to be connected to a device under test with an impedance mismatched interface (63), wherein the calibration arrangement comprises means for calibrating the monitoring device comprising means (51, 55, 57, 59) for propagating a pulse towards the interface, such that a transmitted pulse may be sensed by the monitoring system and a reflected pulse may be sensed by means (61) for sensing in the calibration arrangement.

14. Device as claimed in claim 9, wherein the device is a device for monitoring a high-voltage system.

15. Device as claimed in claim 14, wherein the device is a device for detecting partial discharge conditions in a cable.

16. Device as claimed in claim 14, wherein the device is a device for detecting transient conditions.

17. A method according to claim 2, wherein further a signal (V⁺), corresponding to a pulse propagating in a direction opposite to said one direction is extracted, as a linear combination of the first and second frequency-domain signals.

18. A method according to claim 2, wherein a signal (V⁻), extracted in the frequency domain, is inversely transformed (47) to the time domain (v⁻(t)).

19. A method according to claim 3, wherein a signal (V⁻), extracted in the frequency domain, is inversely transformed (47) to the time domain (v⁻(t)).

20. A method according to claim 2, wherein a calibration procedure of a monitoring system to be used for said detection of the propagating direction of a pulse is carried out by attaching a calibration arrangement to a system under test with an impedance mismatched interface, and propagating a pulse towards the interface, such that a transmitted pulse may be sensed by the monitoring system and a reflected pulse may be sensed by the calibration arrangement.
